(19) United States
(12) Patent Application Publication
(10) Pub. No.: US 2012/0077009 A1
(43) Pub. Date: Mar. 29, 2012

(54) COATING, ARTICLE COATED WITH COATING, AND METHOD FOR MANUFACTURING ARTICLE

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); CHUANG MA, Shenzhen (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/031,706

(22) Filed: Feb. 22, 2011

(30) Foreign Application Priority Data
Sep. 23, 2010 (CN) 201010289292.7

(51) Int. Cl. B32B 15/04; C04B 35/58; C23C 14/16; B32B 9/00; C23C 14/35

(52) U.S. Cl. 428/220; 428/336; 428/697; 428/457; 204/192.15; 501/96.1

(57) ABSTRACT

A coating includes a deposited layer. The deposited layer is a zirconium yttrium nitride layer.

### BACKGROUND

1. Technical Field

The exemplary disclosure generally relates to coatings, and particularly relates to articles coated with the coatings and a method for manufacturing the articles.

2. Description of Related Art

Physical vapor deposition (PVD) has conventionally been used to form a coating on metal bases of cutting tools or molds. Materials used as this coating material are required to have excellent hardness and toughness. At present, Titanium nitride (TiN) and Titanium-aluminum nitride (TiAlN) are mainly used as a material satisfying these requirements. However, these coating materials have a poor adhesion to metal bases and may be easily peeled off.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary coating, article coated with the coating and method for manufacturing the article. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary embodiment of coating.

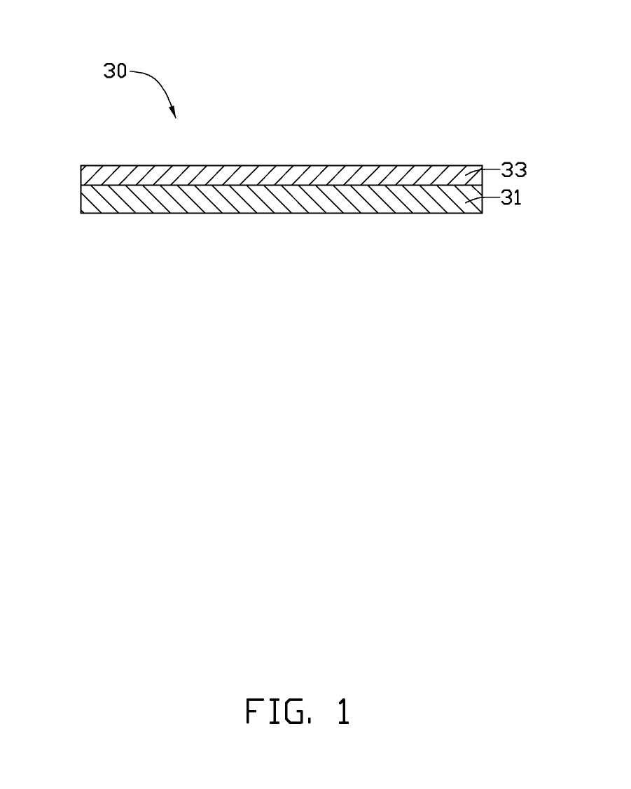

FIG. 2 is a cross-sectional view of an article coated with the coating in FIG. 1.

FIG. 3 is a schematic view of a magnetron sputtering coating machine for manufacturing the article in FIG. 2.

### DETAILED DESCRIPTION

A coating 30 includes a deposited layer 31. The deposited layer 31 is a zirconium yttrium nitride (ZrYN) layer. The deposited layer 31 may be deposited by magnetron sputtering.

The deposited layer 31 has a thickness of about 0.5 micrometers (μm) to about 3 micrometers, and in this exemplary embodiment is about 2 micrometers. The micro-hardness of the coating 30 is about 47 GPa. The coating 30 may also include a color layer 33 covering the deposited layer 31, to decorate the coating 30.

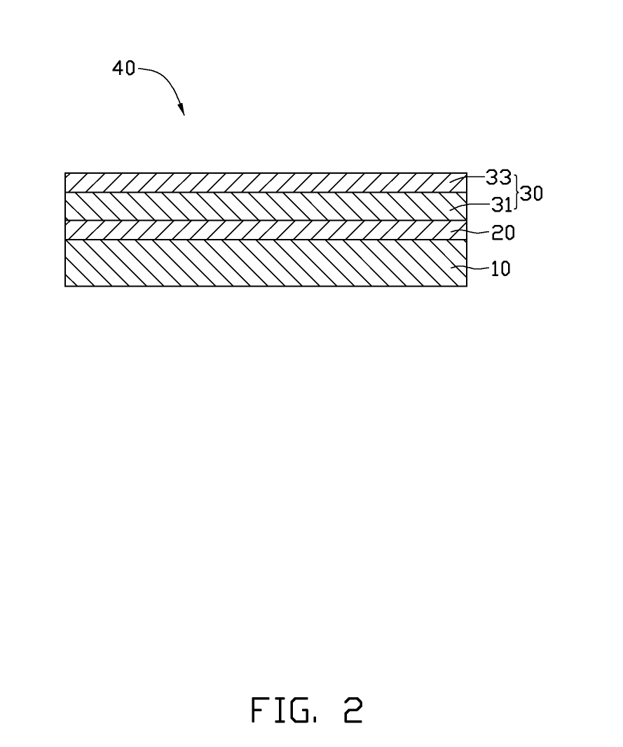

Referring to FIG. 2, an exemplary article 40 includes a substrate 10, a bonding layer 20 deposited on the substrate 10 and the coating 30 deposited on the bonding layer 20. The substrate 10 may be made of metal, such as high speed steel, hard alloy, or stainless steel. The article 40 may be a cutting tool, mold, or housing of an electronic device. The bonding layer 20 is a zirconium yttrium (ZrY) layer. The bonding layer 20 has a thickness of about 50 nanometers to about 200 nanometers, and in this exemplary embodiment has about 100 nanometers. The bonding layer 20 can be deposited by magnetron sputtering. The chemical stability of the bonding layer 20 is between the chemical stability of the substrate 10 and the chemical stability of the coating 30, and the coefficient of thermal expansion of the bonding layer 20 is between the coefficient of thermal expansion of the substrate 10 and the coefficient of thermal expansion of the coating 30. Thus, the bonding layer 20 improves the binding force between the substrate 10 and the coating 30 so the coating 30 can be firmly deposited on the substrate 10.

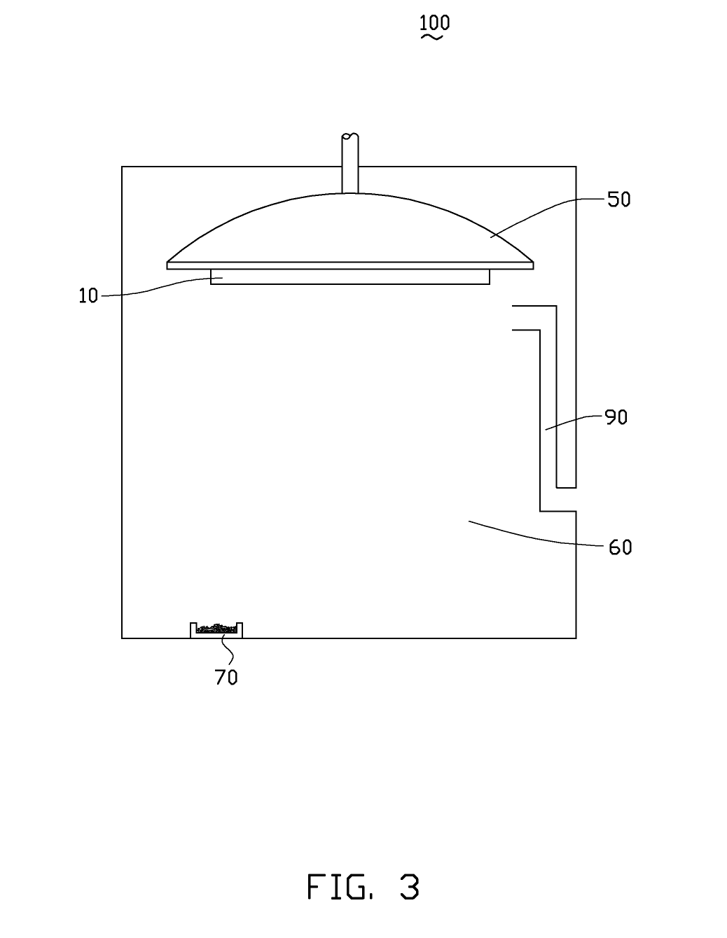

Referring to FIG. 3, a method for manufacturing the article 40 may include at least the following steps:

Providing a substrate 10. The substrate 10 may be made of high speed steel, hard alloy, or stainless steel.

Pretreating the substrate 10 by washing with a solution (e.g., deionized water or alcohol) in an ultrasonic cleaner, to remove, e.g., grease, dirt, and/or impurities, then drying the substrate 10. Then the substrate 10 is cleaned by argon plasma cleaning. The substrate 10 is retained on a rotating bracket 50 in a vacuum chamber 60 of a magnetron sputtering coating machine 100. The vacuum level of the vacuum chamber 60 is set to about 1.0×10⁻³ Pa. Argon is floated into the vacuum chamber 60 at a flux from about 250 Standard Cubic Centimeters per Minute (sccm) to 500 sccm from a gas inlet 90. Then a bias voltage is applied to the substrate 10 in a range from about −300 volts to about −500 volts for about 3-5 minutes. Thereby, the substrate 10 is washed by argon plasma, to further remove any grease or dirt. Thus, the binding force between the substrate 10 and the bonding layer 20 is enhanced.

A bonding layer 20 is deposited on the substrate 10. Argon is floated into the vacuum chamber 60 at a flux from about 100 sccm to about 200 sccm from the gas inlet 90. The temperature of the vacuum chamber 60 is set to between about 100 degrees Celsius (° C.) and about 200° C. A zirconium yttrium alloy target 70 is evaporated at a power of about 5 kW to about 11 kW. A bias voltage applied to the substrate 10 may be in a range from about −100 volts to about −300 volts for about 20 min to about 60 min, to deposit the bonding layer 20 on the substrate 10. The zirconium yttrium alloy contains atomic zirconium of about 70 to about 90 wt %.

A deposited layer 31 is deposited on the bonding layer 20. The temperature in the vacuum chamber 60 is set to between about 100° C. and about 200° C. Nitrogen is floated into the vacuum chamber 60 at a flux of about 10 sccm to about 100 sccm and argon is floated into the vacuum chamber 60 at a flux of about 100 sccm to 200 sccm from the gas inlet 90. The zirconium yttrium alloy target 70 is continuously evaporated in a power of about 5 kW to about 11 kW. A bias voltage applied to the substrate 10 may be about −100 volts to about −250 volts for about 60 min to about 180 min, to deposit the deposited layer 31 on the bonding layer 20.

During depositing the deposited layer 31, atomic yttrium cannot react with atomic zirconium and atomic nitrogen to form solid solution phrase, and atomic yttrium is independently formed to yttrium phrase at the boundary of the zirconium-nitrogen crystal, which can prevent the zirconium-nitrogen crystal from enlarging, to maintain the zirconium-nitrogen crystal in nanometer level. The nanometer lever zirconium-nitrogen can improve hardness and toughness of the coating 30.

When the coating 30 is located in high temperature and oxygen environment, the atomic yttrium in the coating 30 can prevent exterior oxygen from diffusing in the coating 30. Thereby, the coating 30 has high temperature oxidation resistance.

It is to be understood that the color layer 33 may be deposited on the deposited layer 31 to improve the appearance of the article 40.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

1-6. (canceled)

7. An article, comprising:
a substrate;
a bonding layer deposited on the substrate; and
a deposited layer deposited on the bonding layer, wherein the deposited layer is a zirconium yttrium nitride layer;
wherein the bonding layer is a zirconium yttrium layer having a thickness of about 50 nanometers to about 200 nanometers.

8. The article as claimed in claim 7, wherein the bonding layer and the deposited layer is deposited by magnetron sputtering.

9. The article as claimed in claim 7, wherein the deposited layer has a thickness of about 0.5 micrometers to about 3 micrometers.

10. The article as claimed in claim 7, wherein the deposited layer has a thickness of about 2 micrometers.

11. The article as claimed in claim 7, wherein the micro-hardness of the coating is about 47 GPa.

12. The article as claimed in claim 7, further comprising a color layer formed on the deposited layer, to decorate the appearance of the article.

13. The article as claimed in claim 7, wherein the substrate is made of high speed steel, hard alloy, or stainless steel.

14. (canceled)

15. The article as claimed in claim 7, wherein the chemical stability of the bonding layer is between the chemical stability of the substrate and the chemical stability of the coating, and the coefficient of thermal expansion of the bonding layer is between the coefficient of thermal expansion of the substrate and the coefficient of thermal expansion of the coating.

16-19. (canceled)
